(19) United States
(12) Patent Application Publication
(10) Pub. No.: US 2018/0096879 A1
(43) Pub. Date: Apr. 5, 2018

(54) SPIN CHUCK INCLUDING EDGE RING

(71) Applicant: Lam Research AG, Villach (AT)

(72) Inventors: Shih-Chung Kon, Fremont, CA (US); Milan Pliska, Villach (AT); Bernhard Loidl, Villach (AT); Michael Brugger, Millstatt (AT)

(21) Appl. No.: 15/285,894

(22) Filed: Oct. 5, 2016

(51) Int. Cl. H01L 21/687

(52) U.S. Cl. CPC H01L 21/68735; H01L 21/68728

(57) ABSTRACT

Apparatus for treating a substrate includes a stationary plate assembly including liquid nozzles to direct liquid at an edge of the substrate during treatment. A chuck assembly includes a chuck body arranged below and radially outside of the stationary plate assembly and rotatable relative to the stationary plate assembly. An edge ring is attached to the chuck body and defines a radially inner surface extending in an axial direction above and below a plane including the substrate. The edge ring is located radially outside of a radially outer edge of the substrate along an entire surface of the edge ring. A plurality of pins is movable between a clamping position to engage the radially outer edge of the substrate and an idle position.

### FIELD

The present disclosure relates to substrate processing systems, and more particularly to a spin chuck including an edge ring.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrates such as semiconductor wafers are subjected to surface treatment processes including etching, cleaning, polishing and deposition. For wet bevel applications, film on the substrate is etched or cleaned close to a radially outer edge of the substrate.

A spin chuck may be used for wet bevel applications. The spin chuck includes a stationary plate assembly including gas nozzles and liquid nozzles. The spin chuck also includes a rotating chuck assembly located radially outside of the stationary plate. Multiple pins that are connected to the rotating chuck assembly are used to grip a radially outer edge of the substrate. The gas nozzles of the stationary plate assembly support the substrate on a cushion of gas (according to Bernoulli's principle). The liquid nozzles direct etching/cleaning fluid at an edge of the substrate. The rotating chuck assembly rotates the substrate relative to the gas and liquid nozzles of the stationary plate.

To etch/clean the edge of the substrate, the liquid nozzles are located close to the edge of the substrate and are directed at a desired location on the substrate. As the substrate rotates, process liquid impinges on an undercut area and is spun off due to centrifugal force of rotation. The combination of impingement location, substrate rotation, flow rate, nozzle angle and other design parameters determines the undercut size.

However, the pins tend to disturb liquid flowing near the undercut area and create pin marks on the substrate during etching/cleaning. The pin marks reduce device yield and increase fabrication costs.

Some etch/clean processes have eliminated pin marks by engaging the substrate using a different approach. Instead of gripping the substrate using the pins, a backside of the substrate is held by a vacuum chuck. When the vacuum chuck is used, pin marks are not an issue since there is nothing at the edge of the substrate to disturb the flow of the etching/cleaning fluid. However, vacuum suction formed between the chuck and the substrate scratches the backside of the substrate and/or embeds particles into the substrate.

### SUMMARY

Apparatus for treating a substrate includes a stationary plate assembly including liquid nozzles to direct liquid at an edge of the substrate during treatment. A chuck assembly includes a chuck body arranged below and radially outside of the stationary plate assembly and rotatable relative to the stationary plate assembly. An edge ring is attached to the chuck body and defines a radially inner surface extending in an axial direction above and below a plane including the substrate. The edge ring is located radially outside of a radially outer edge of the substrate along an entire surface of the edge ring. A plurality of pins is movable between a clamping position to engage the radially outer edge of the substrate and an idle position.

In other features, the plurality of pins is rotatable relative to the chuck body. The radially inner surface of the edge ring includes a plurality of recesses for receiving at least part of the plurality of pins when the plurality of pins is in the clamping position. Each of the plurality of pins includes a gripping end that is cylindrically-shaped or prism-shaped. A surface of the gripping ends for contacting the substrate is parallel to an axis of rotation of the substrate.

In other features, each of the plurality of pins includes a gripping end. The radially inner surface of the edge ring includes a plurality of arcuate recesses for receiving at least part of the gripping ends.

In other features, each of the plurality of pins includes a gripping end that is cylindrically-shaped. A gap between the substrate and the radially inner surface of the edge ring is less than or equal to a diameter of the gripping ends.

In other features, the stationary plate assembly includes gas nozzles to supply gas in an upward direction towards the substrate to support the substrate at a floating height above the stationary plate assembly during treatment. A liquid meniscus is created by the liquid nozzles between the substrate and the edge ring during treatment.

In other features, a floating height of the substrate above the stationary plate assembly is in a range from 0.2 mm to 0.5 mm. A distance between an upper surface of the stationary plate assembly and an upper edge of the radially inner surface of the edge ring is in a range from 1.3 mm to 2.5 mm. A distance between a radially outer edge of the stationary plate assembly and the radially inner surface of the edge ring is in a range from 0.1 mm to 0.7 mm.

In other features, a distance between the stationary plate assembly and a lower edge of the radially inner surface of the edge ring is in a range from −0.2 mm to 1.5 mm. A distance between an upper surface of the stationary plate assembly and a lower edge of the radially inner surface of the edge ring is in a range from 0.5 mm to 2.0 mm. A distance between an upper surface of the substrate and an upper edge of the radially inner surface of the edge ring is in a range from 0.5 mm to 2.0 mm.

In other features, the radially inner surface of the edge ring includes recesses and defines a cylindrical surface along portions of the radially inner surface excluding the recesses. The radially inner surface of the edge ring is less than or equal to +/−5° from a line parallel to an axis of rotation of the chuck assembly. The radially inner surface of the edge ring is less than or equal to +/−10° from a line parallel to an axis of rotation of the chuck assembly within a distance 2.0 mm above an upper surface of the substrate and 2.0 mm below a lower surface of the substrate.

In other features, the radially inner surface of the edge ring is concave. The radially inner surface of the edge ring is convex.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of an example of a spin chuck assembly according to the present disclosure;

FIG. 2 is a schematic side cross-sectional view of an example of a spin chuck assembly according to the present disclosure;

FIG. 3 is a partial perspective view of an example of an edge ring, stationary plate assembly and chuck assembly according to the present disclosure;

FIG. 4 is a side partial perspective view of an example of the edge ring according to the present disclosure;

FIG. 5 is a partial perspective view of an example illustrating the edge ring, a pin recess, and a pin located in an idle position;

FIG. 6 is a partial perspective view of an example illustrating the edge ring, the pin recess, and the pin located in a clamping position;

FIGS. 7A-7E are side cross-sectional views of additional examples of edge ring profiles; and

FIG. 8 is a side cross-sectional view illustrating example dimensions.

In the drawings, reference numbers may be reused to identify similar and/or identical elements.

### DETAILED DESCRIPTION

The present disclosure relates to a spin chuck including an edge ring. The spin chuck includes a stationary plate assembly with gas nozzles and liquid nozzles. The spin chuck further includes a rotating chuck assembly located radially outside of the stationary plate assembly. The rotating chuck assembly includes an edge ring that reduces or eliminates pin marks. Multiple pins that are connected to the rotating chuck assembly contact a radially outer edge of the substrate. The gas nozzles of the stationary plate assembly support the substrate on a cushion of gas (according to Bernoulli's principle). The liquid nozzles direct etching/cleaning fluid at the substrate. The rotating chuck assembly rotates the substrate relative to the gas and liquid nozzles of the stationary plate assembly.

The edge ring reduces or eliminates the pin marks that would otherwise be visible on the substrate after treatment. Due to the relative arrangement and dimensions of the edge ring, the edge ring mimics having an infinite number of pins arranged around the edge of the substrate. More particularly, the edge ring minimizes disturbance and discontinuity at the edge of the substrate. As a result, the spin chuck according to the present disclosure provides a uniform undercut all around the edge of the substrate (without pin marks) despite being clamped by the pins.

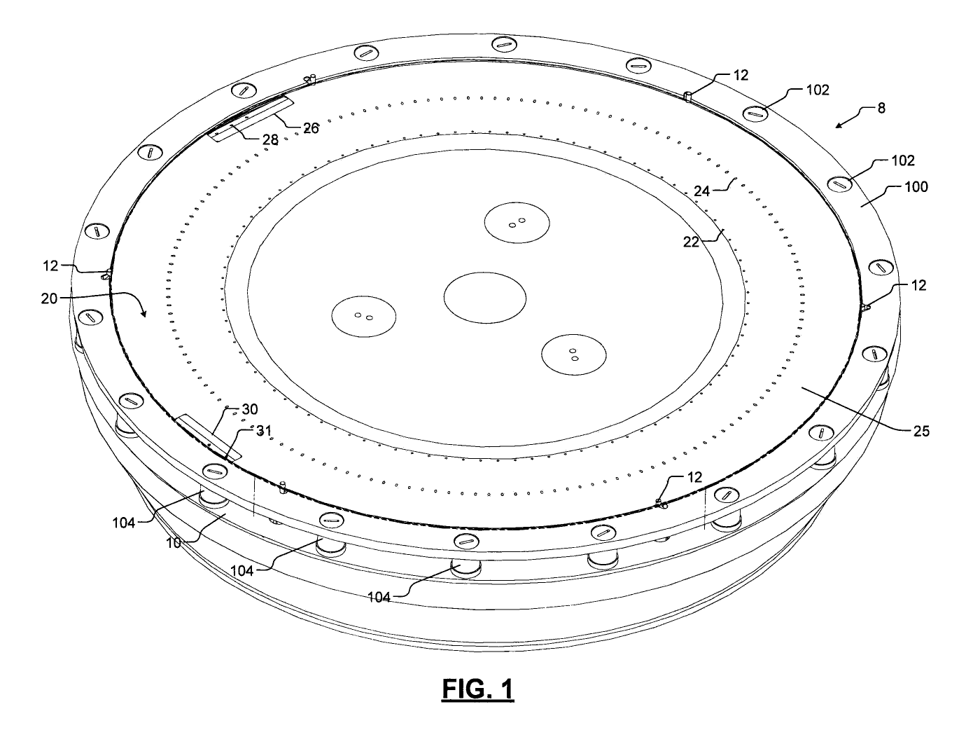

Referring now to FIGS. 1 and 2, a spin chuck 8 according to the present disclosure is shown. In FIG. 1, the spin chuck 8 includes a rotating chuck assembly 10 including a plurality of pins 12 that selectively clamp and release a radially outer edge of a substrate S (shown in FIG. 2). In some examples, three or more pins 12 are used. The pins 12 include gripping ends 14 (shown in FIG. 2) that are located at a distal end thereof and that contact the substrate S during processing of the substrate S. In some examples, the pins 12 extend parallel to the axis of rotation of the rotating chuck assembly 10. In some examples, the pins 12 provide lateral but not subjacent support for the substrate S.

In some examples, the gripping ends 14 of the pins 12 are eccentric to the axes of rotation of the pins 12 as shown in commonly-assigned U.S. Pat. No. 8,029,641, which issued on Oct. 4, 2011 and is entitled “Device and Method for Liquid Treatment of Wafer-Shaped Articles”, and which is hereby incorporated by reference in its entirety. The gripping ends 14 are movable between a clamping position and an idle position. While the pins 12 may be rotatable relative to the rotating chuck assembly 10 to clamp and unclamp the substrate S, the pins 12 can be tilted, moved radially, moved axially and radially, and/or moved in any other direction to clamp and unclamp the substrate S. The gripping ends 14 may be fully or partially cylindrically-shaped, prism-shaped or any other suitable shape. The rotating chuck assembly 10 is configured to hold a substrate having a predetermined diameter, for example a 300 mm diameter or 450 mm diameter substrate (a semiconductor wafer), although other sized substrates can be used.

A fluid distribution manifold 20 is stationary and is positioned radially inside of the pins 12 and beneath the substrate S during processing. Fluid distribution manifold 20 includes a stationary plate assembly 25 that includes gas nozzles 22, 24. In some examples, the gas nozzles 22, 24 are formed as a single continuous annular nozzle, or a circular series of arcuate nozzles.

Liquid nozzle assemblies 26, 30 are removably attached to the fluid distribution manifold 20 and the stationary plate assembly 25. The liquid nozzle assemblies 26, 30 include liquid discharge orifices 28, 31 that discharge process liquid upwardly and/or radially outwardly onto the downwardly facing surface of the substrate S along a radially outer edge thereof. An edge ring 100 according to the present disclosure is connected to the rotating chuck assembly 10 by optional fasteners 102 and/or optional spacers 104, although other attachment methods can be used. Alternately, the edge ring 100 can be integrated with a chuck body (described below).

In FIG. 2, the rotating chuck assembly 10 includes a chuck body including a lower chuck portion 11 and an upper chuck portion 13 that are rigidly connected. The chuck body is mounted for rotation about a stationary central post 50, which is mounted on a support frame 36. A stator 32 is mounted on the support frame 36. The rotor 34 and the stator 32 rotate the rotating chuck assembly 10.

The fluid distribution manifold 20 including the stationary plate assembly 25 is rigidly mounted to the stationary central post 50. The rotating chuck assembly 10 surrounds the fluid distribution manifold 20. The rotating chuck assembly 10 also includes a ring gear 15 located between the lower chuck portion 11 and the upper chuck portion 13. The ring gear 15 includes outwardly projecting teeth that are coaxial with the rotating chuck assembly 10 and that engage complementary teeth formed at the base of the pins 12. Rotation of the chuck body and the ring gear 15 against each other thereby rotates the pins 12.

The stationary central post 50 comprises liquid conduits 56 and 57, which are supplied with process liquid from a supply thereof. Liquid conduits 56, 57 communicate with liquid conduits 27 and 29, respectively, formed in the fluid distribution manifold 20. The liquid conduits 27 and 29 communicate with the liquid nozzle assemblies 26 and 30 in FIG. 1.

The stationary central post 50 also includes gas conduits 54, which are connected to a source of gas. In some examples, the gas includes molecular nitrogen (N₂), although other gases can be used. The gas conduits 54 open at their downstream ends into the chamber 23 formed in the fluid distribution manifold 20. The chamber 23 communicates with the gas nozzles 24. In some examples, the gas nozzles 24 include bores formed in the stationary plate assembly 25 that extend obliquely from a radially inner inlet to a radially outer outlet.

The stationary central post 50 includes a gas conduit 52, which is likewise connected to a source of gas. In some examples, the gas includes molecular nitrogen (N₂), although other gases can be used. The gas conduit 52 opens at its downstream end into the chamber 21 formed in fluid distribution manifold 20. Chamber 21 communicates with the gas nozzles 22, which, as shown in FIG. 2, include bores formed in the stationary plate assembly 25 that extend axially through the stationary plate assembly 25.

A liquid dispenser 45 dispenses liquid onto the upwardly-facing surface of substrate S. The liquid dispenser 45 may for example take the form of an arm that moves the downwardly-depending discharge nozzle along an arc above the upper surface of the substrate S to be processed.

A heater 40 may be used to heat the substrate S during processing. In some examples, the heater 40 includes a radiant heating assembly. In some examples, the heater 40 includes LED heating elements 42, which are shielded from the process environment by a window 44 that is made of material transparent to the radiation emitted by the heater 40. In some examples, the window 44 is made of a material such as quartz or sapphire, although other materials can be used.

In use, gas is supplied through the gas nozzles 22 and/or 24 to provide a gas cushion for the substrate S. The substrate S is positioned above and parallel to the stationary plate assembly 25. The flow rate of gas through the gas nozzles 22 and/or 24 is adjusted so that the substrate S is supported according to the Bernoulli principle. The rotating chuck assembly 10 rotates the substrates while the process fluid is directed at the undercut region.

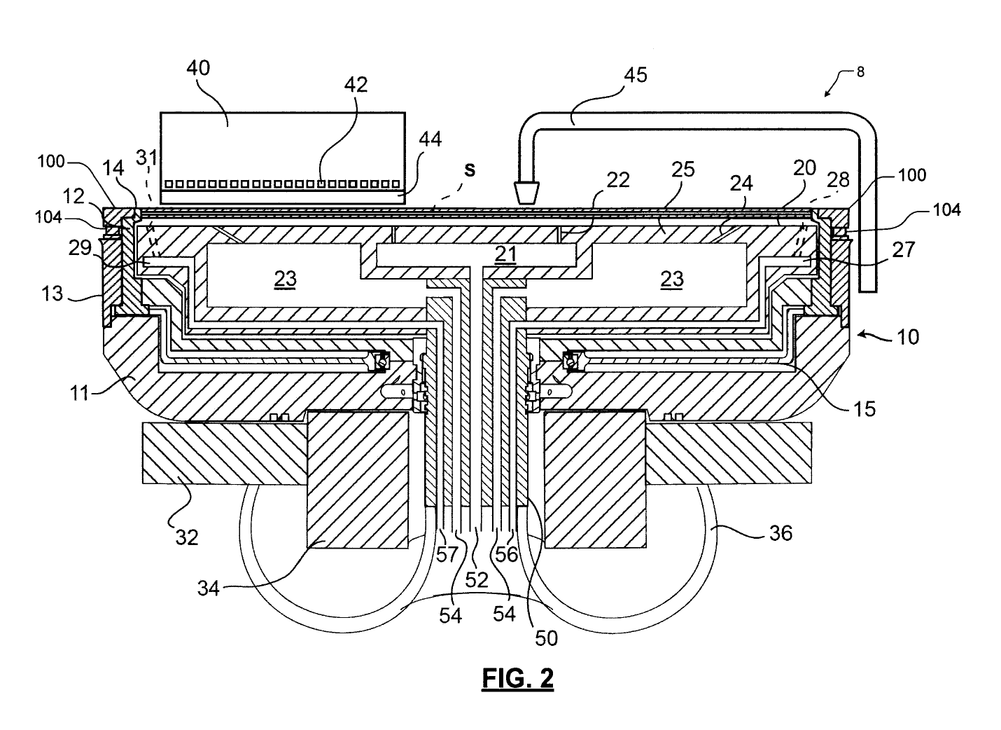

Referring now to FIG. 3, an example of the edge ring 100, the stationary plate assembly 25 and the rotating chuck assembly 10 is shown. The edge ring 100 includes a radially inner surface 120. The radially inner surface 120 extends both above and below upper and lower surfaces of the substrate S (not shown in FIG. 3). The edge ring 100 further includes a plurality of recesses 124 that are defined in the radially inner surface 120 to receive the gripping end 14 of the pins 12. The radially inner surface 120 defines a generally cylindrical surface (e.g. parallel to the axis of rotation of the rotating chuck assembly 10) in surface portions of the radially inner surface 120 excluding the recesses 124.

In some examples, the recesses 124 are spaced apart by 360°/N, where N is the number of recesses 124, although non-uniform spacing can be used. In some examples, N=6, although additional or fewer pins can be used. The recesses 124 provide clearance to receive all or a portion of the gripping end 14. For example only, the plurality of recesses 124 may be “C” shaped, slotted, arcuate-shaped or partially circular-shaped, although other shapes can be used.

Referring now to FIG. 4, an arcuate segment of the edge ring 100 is shown. The radially inner surface 120 of the edge ring 100 defines an upper edge 150 that is located above the upper surface of the substrate S during processing. A lower edge 156 of the radially inner surface 120 is located below the lower surface of the substrate S during processing. In this example, the radially inner surface 120 defines cylindrical surface that is parallel to an axis of rotation of the rotating chuck assembly 10 along an entire surface of the radially inner surface 120 excluding the recesses 124. In other words, the radially inner surface 120 may define a cylindrical surface. However, the radially inner surfaces may vary less than or equal to +/−5° or 10° from a line parallel to the axis of rotation of the rotating chuck assembly 10. In some examples, the lower edge 156 is also located below a top surface of the stationary plate assembly 25.

Other than the recesses 124, the radially inner surface 120 provides a continuous surface against which the process liquid impinges during processing. In some examples, the process liquid is projected radially outward by centrifugal force against the radially inner surface 120 and bounces back in a direction towards the substrate S. A liquid meniscus is formed. In addition, a fluid standing wave may be created. As a result, treatment of the radially outer edge can be performed without leaving pin marks.

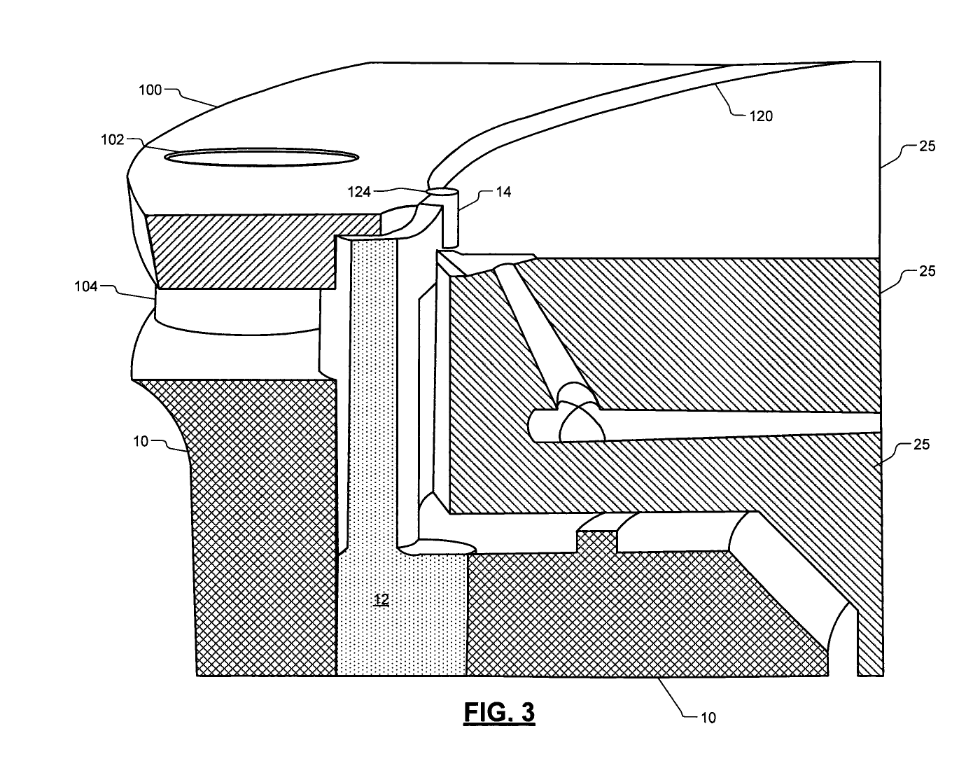

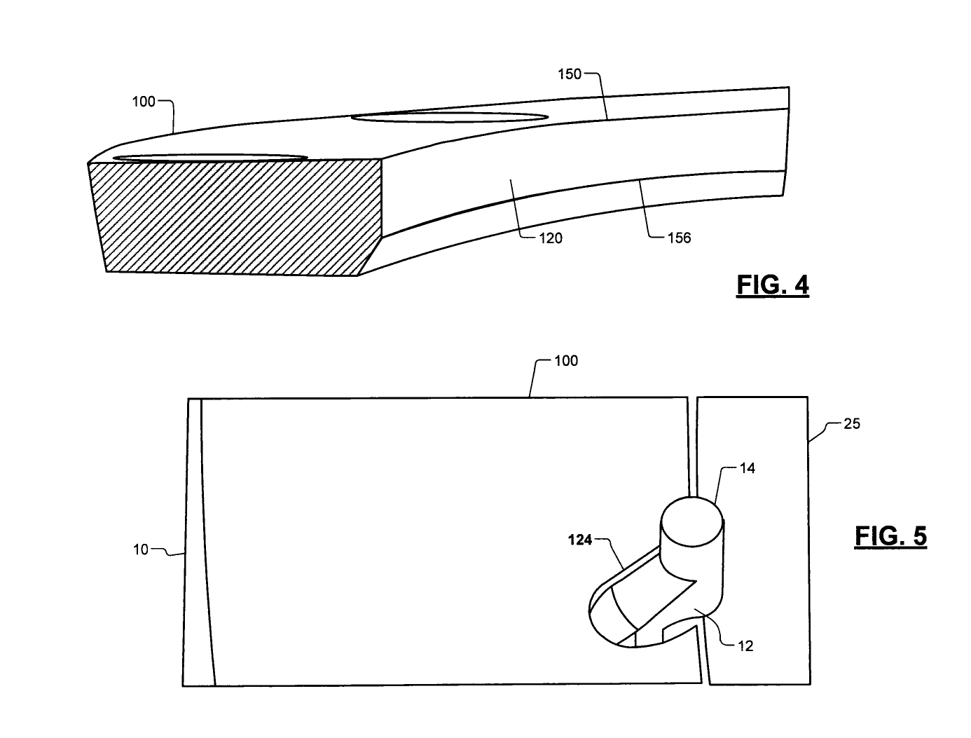

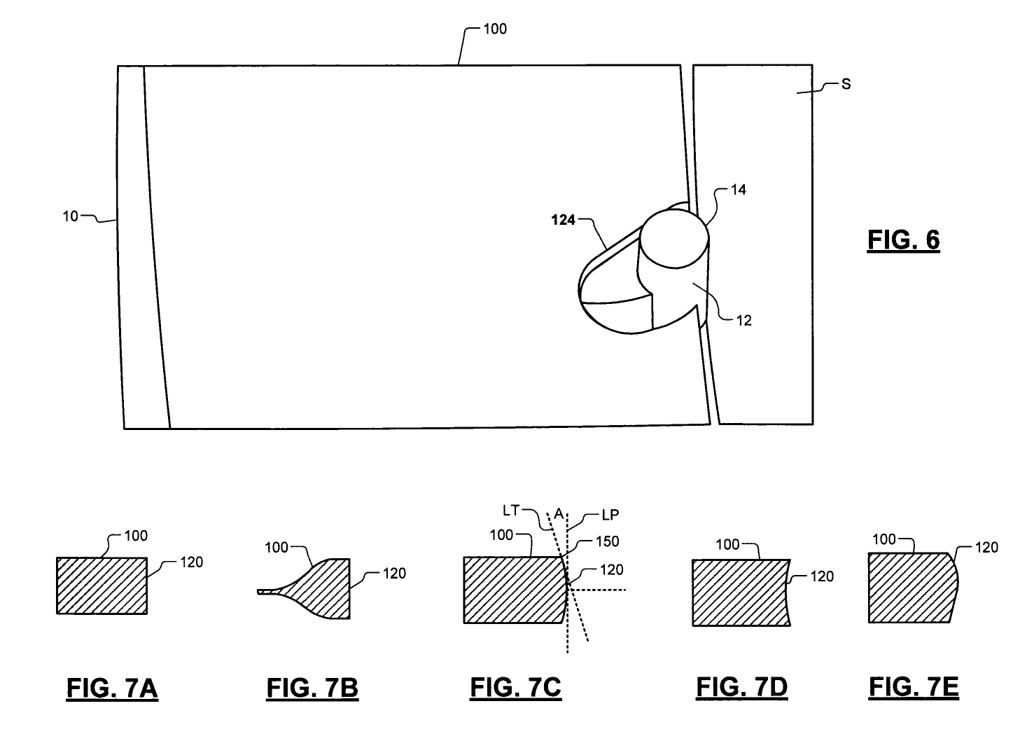

Referring now to FIGS. 5-6, the edge ring 100 is shown with the gripping end 14 arranged in various positions. In FIG. 5, the edge ring 100 is shown with the gripping end 14 arranged in an idle position when a substrate is not located on the stationary plate assembly 25. In FIG. 6, the edge ring 100 is shown with the gripping end 14 arranged in a clamping position against the substrate S when the substrate S is located on the stationary plate assembly 25.

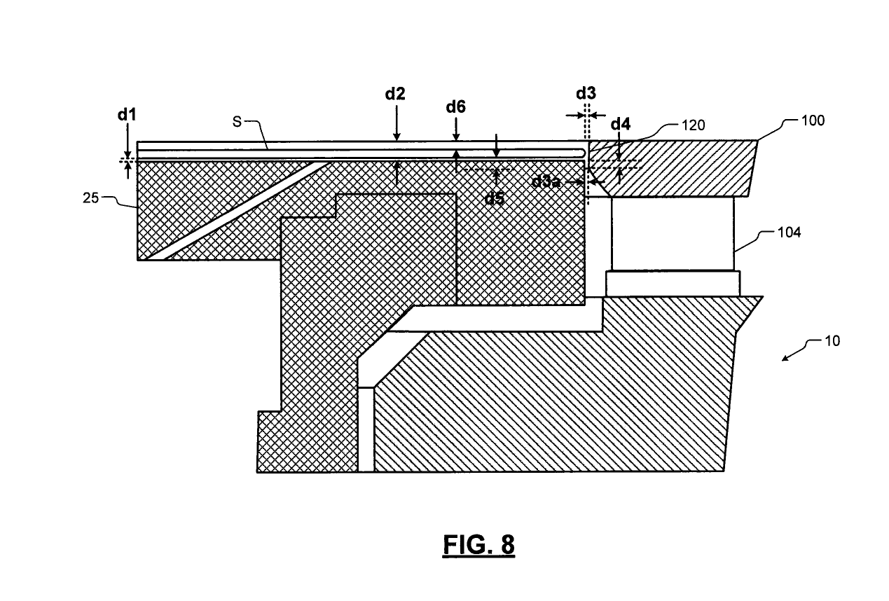

Referring now to FIGS. 7A-7E, while the edge ring is shown in FIGS. 3 and 4 with a specific cross-section, other cross-sections may be used. For example, in FIGS. 7A and 7B, rectangular or tapered cross-sections may be used. The radially inner surface 120 of the edge rings 100 in these examples is parallel to the axis of rotation of the chuck. In FIGS. 7C-7E, the radially inner surface 120 of the edge ring 100 can have some curvature. Convex or concave surfaces can be used.

In FIG. 7C, the radially inner surface 120 is convex. A line LT that is tangent to the radially inner surface 120 of the edge ring 100 at the upper edge 150 of the radially inner surface 120 forms an angle A with a line LP parallel to the axis of rotation that is less than a predetermined angle. In some examples, the predetermined angle is less than or equal to +/−5° or 10° within a distance less than or equal to 2 mm of the upper and/or lower surfaces of the substrate S.

Referring now to FIG. 8, examples of dimensions between various elements are shown. In some examples, a floating height d1 of the substrate S above the stationary plate assembly 25 is in a range from 0.2 mm to 0.5 mm. In some examples, the floating height d1 of the substrate S above the stationary plate assembly 25 is in a range from 0.25 mm to 0.35 mm. In some examples, the floating height d1 of the substrate S above the stationary plate assembly 25 is 0.3 mm.

In some examples, an axial distance d2 between the upper surface of the stationary plate assembly 25 and the upper edge 150 of the radially inner surface 120 of the edge ring 100 is in a range from 1.3 mm to 2.5 mm. In some examples, the axial distance d2 between the upper surface of the stationary plate assembly 25 and the upper edge 150 of the radially inner surface 120 of the edge ring 100 is in a range from 1.6 mm to 2 mm. In some examples, the axial distance d2 between the stationary plate assembly 25 and the upper edge 150 of the radially inner surface 120 of the edge ring 100 is 1.8 mm.

In some examples, a radial distance d3 between the substrate S edge and the radially inner surface 120 of the edge ring 100 is in a range from 0.1 mm to 0.7 mm. In some examples, the radial distance d3 between the substrate S edge and the radially inner surface 120 of the edge ring 100 is in a range from 0.2 mm to 0.4 mm. In some examples, a radial distance d3 between the substrate S edge and the radially inner surface 120 of the edge ring 100 is 0.3 mm. In some examples, a radial distance d3a between the edge of the stationary plate assembly 25 and the radially inner surface 120 of the edge ring 100 is in a range from 0.1 mm to 0.7 mm. In some examples, the radial distance d3a between the edge of the stationary plate assembly 25 and the radially inner surface 120 of the edge ring 100 is in a range from 0.2 mm to 0.4 mm. In some examples, a radial distance d3a between the edge of the stationary plate assembly 25 and the radially inner surface 120 of the edge ring 100 is 0.3 mm.

In some examples, an axial distance d4 between the upper surface of the stationary plate assembly 25 and the lower edge 156 of the radially inner surface 120 of the edge ring is in a range from −0.2 mm to 1.5 mm. In some examples, the axial distance d4 between the upper surface of the stationary plate assembly 25 and the lower edge 156 of the radially inner surface 120 of the edge ring is in a range from 0.3 mm to 0.5 mm. In some examples, the axial distance d4 between the stationary plate assembly 25 and the lower edge 156 of the radially inner surface 120 of the edge ring is 0.4 mm.

In some examples, a distance d5 between the lower substrate S surface and the lower edge of the radially inner surface 120 of the edge ring is in a range from 0.5 mm to 2.0 mm. In some examples, the distance d5 between the lower substrate S surface and the lower edge of the radially inner surface 120 of the edge ring is in a range from 0.6 mm to 0.8 mm. In some examples, the distance d5 between the lower substrate S surface and the lower edge of the radially inner surface 120 of the edge ring is 0.7 mm.

In some examples, an axial distance d6 between the upper surface of the substrate S and the upper edge 150 of the radially inner surface 120 of the edge ring 100 is in a range from 0.5 mm to 2.0 mm. In some examples, the axial distance d6 between the upper surface of the substrate S and the upper edge 150 of the radially inner surface 120 of the edge ring 100 is in a range from 0.6 mm to 0.8 mm. In some examples, the axial distance d6 between the upper surface of the substrate S and the upper edge 150 of the radially inner surface 120 of the edge ring 100 is 0.7 mm.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. Apparatus for treating a substrate, comprising:
a stationary plate assembly including liquid nozzles to direct liquid at an edge of the substrate during treatment; and
a chuck assembly including:
a chuck body arranged below and radially outside of the stationary plate assembly and rotatable relative to the stationary plate assembly;
an edge ring attached to the chuck body and defining a radially inner surface extending in an axial direction above and below a plane including the substrate, wherein the edge ring is located radially outside of a radially outer edge of the substrate along an entire surface of the edge ring; and
a plurality of pins that is movable between a clamping position to engage the radially outer edge of the substrate and an idle position.

2. The apparatus of claim 1, wherein the plurality of pins is rotatable relative to the chuck body.

3. The apparatus of claim 1, wherein the radially inner surface of the edge ring includes a plurality of recesses for receiving at least part of the plurality of pins when the plurality of pins is in the clamping position.

4. The apparatus of claim 1, wherein each of the plurality of pins includes a gripping end that is cylindrically-shaped or prism-shaped and wherein a surface of the gripping ends for contacting the substrate is parallel to an axis of rotation of the substrate.

5. The apparatus of claim 1, wherein each of the plurality of pins includes a gripping end and wherein the radially inner surface of the edge ring includes a plurality of arcuate recesses for receiving at least part of the gripping ends.

6. The apparatus of claim 1, wherein each of the plurality of pins includes a gripping end that is cylindrically-shaped and wherein a gap between the substrate and the radially inner surface of the edge ring is less than or equal to a diameter of the gripping ends.

7. The apparatus of claim 1, wherein the stationary plate assembly includes gas nozzles to supply gas in an upward direction towards the substrate to support the substrate at a floating height above the stationary plate assembly during treatment.

8. The apparatus of claim 1, wherein a liquid meniscus is created by the liquid nozzles between the substrate and the edge ring during treatment.

9. The apparatus of claim 1, wherein a floating height of the substrate above the stationary plate assembly is in a range from 0.2 mm to 0.5 mm.

10. The apparatus of claim 1, wherein a distance between the stationary plate assembly and an upper edge of the radially inner surface of the edge ring is in a range from 1.3 mm to 2.5 mm.

11. The apparatus of claim 1, wherein a distance between a radially outer edge of the stationary plate assembly and the radially inner surface of the edge ring is in a range from 0.1 mm to 0.7 mm.

12. The apparatus of claim 1, wherein a distance between the stationary plate assembly and a lower edge of the radially inner surface of the edge ring is in a range from −0.2 mm to 1.5 mm.

13. The apparatus of claim 1, wherein a distance between an upper surface of the stationary plate assembly and a lower edge of the radially inner surface of the edge ring is in a range from 0.5 mm to 2.0 mm.

14. The apparatus of claim 1, wherein a distance between an upper surface of the substrate and an upper edge of the radially inner surface of the edge ring is in a range from 0.5 mm to 2.0 mm.

15. The apparatus of claim 1, wherein the radially inner surface of the edge ring includes recesses and wherein the radially inner surface defines a cylindrical surface along portions of the radially inner surface excluding the recesses.

16. The apparatus of claim 1, wherein the radially inner surface of the edge ring is less than or equal to +/−5° from a line parallel to an axis of rotation of the chuck assembly.

17. The apparatus of claim 16, wherein the radially inner surface of the edge ring is less than or equal to +/−10° from a line parallel to an axis of rotation of the chuck assembly within a distance 2.0 mm above an upper surface of the substrate and 2.0 mm below a lower surface of the substrate.

18. The apparatus of claim 16, wherein the radially inner surface of the edge ring is concave.

19. The apparatus of claim 16, wherein the radially inner surface of the edge ring is convex.
